(19) United States
(12) Patent Application Publication
(10) Pub. No.: US 2026/0089934 A1
(43) Pub. Date: Mar. 26, 2026

(54) Memory Circuitry And Methods Used In Forming Memory Circuitry

(71) Applicant: Micron Technology, Inc., Boise, ID (US)

(72) Inventors: D. M. Ramitha Y. P. Rupasinghe, Boise, ID (US); Frank Speetjens, Boise, ID (US); Christopher J. Gambee, Caldwell, ID (US)

(73) Assignee: Micron Technology, Inc., Boise, ID (US)

(21) Appl. No.: 19/311,170

(22) Filed: Aug. 27, 2025

Related U.S. Application Data
(60) Provisional application No. 63/698,229, filed on Sep. 24, 2024.

(51) Int. Cl. H10B 12/00

(52) U.S. Cl. CPC H10B 12/50; H10B 12/09; H10B 12/315; H10B 12/482

(57) ABSTRACT

Memory circuitry comprises vertically-alternating insulative tiers and memory-cell tiers. Memory cells in the memory-cell tiers individually comprise a horizontal transistor, a capacitor that is on a capacitor side of the horizontal transistor, and part of a digitline that is on a digitline side of the horizontal transistor. Insulator material extends from horizontally aside the capacitor side of a top gate in a lower memory-cell tier through the insulative tier that is between an upper and a lower memory-cell tiers to horizontally aside the capacitor side of a bottom gate in the upper memory-cell tier. The insulator material in the upper memory-cell tier and in the lower memory-cell tier has a laterally-outer linearly-straight surface in a vertical cross-section that is through and horizontally-elongated along an axis. The laterally-outer linearly-straight surface being one of vertical, angled from vertical away from the capacitor side by no more than 40°, or angled from vertical toward the capacitor side by no more than 30°. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3 and 4 are diagrammatic cross-sectional views of a portion of a construction that will comprise circuitry in accordance with an embodiment of the invention.

FIGS. 5-27 are diagrammatic sequential sectional and/or enlarged views of the construction of FIGS. 3 and 4, or portions thereof or alternate and/or additional embodiments, in process in accordance with some embodiments of the invention.

### DETAILED DESCRIPTION OF EXAMPLE EMBODIMENTS

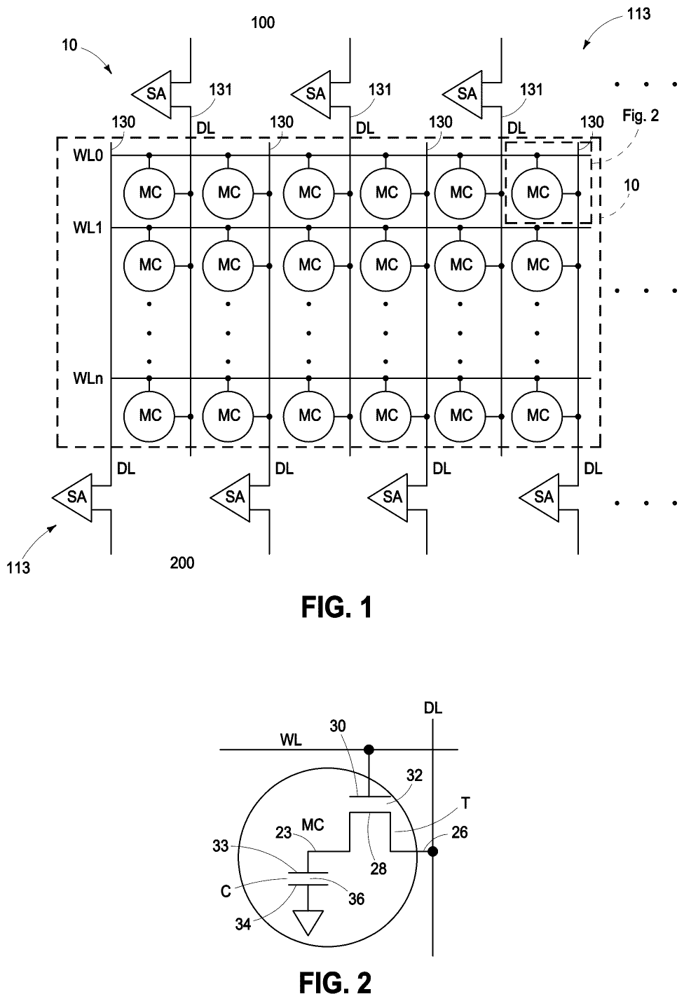

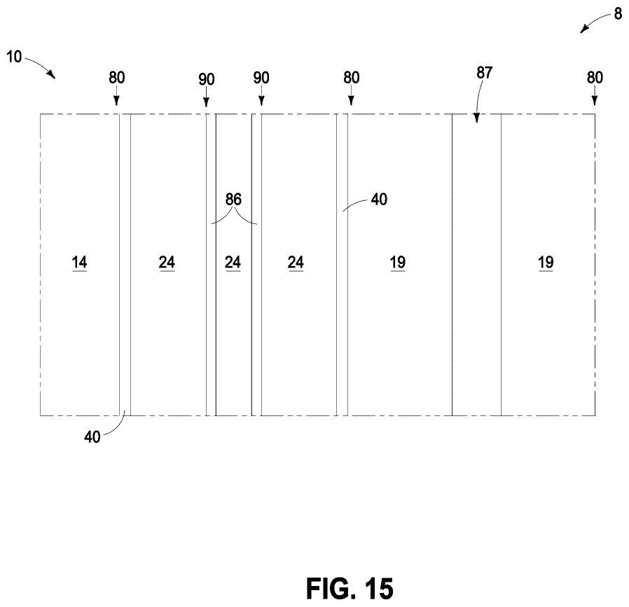

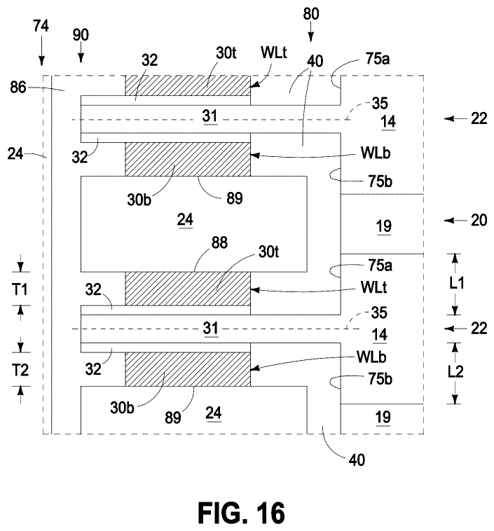

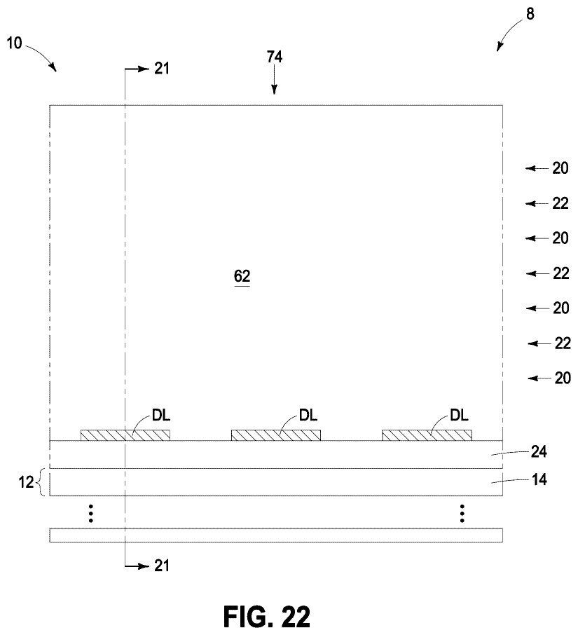

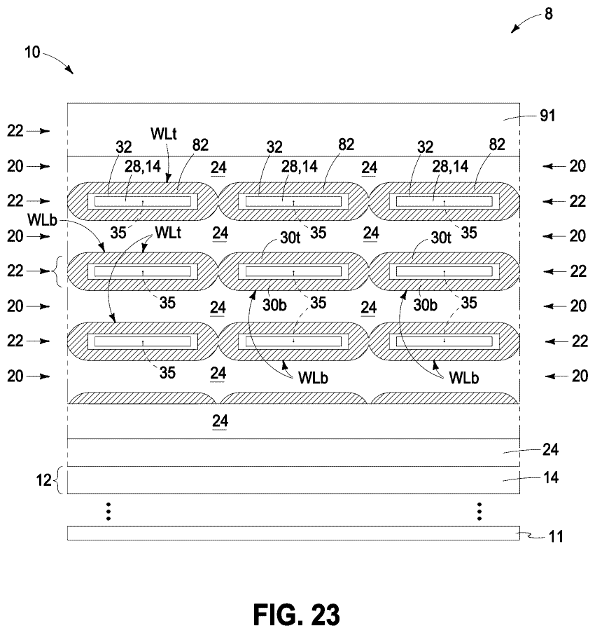

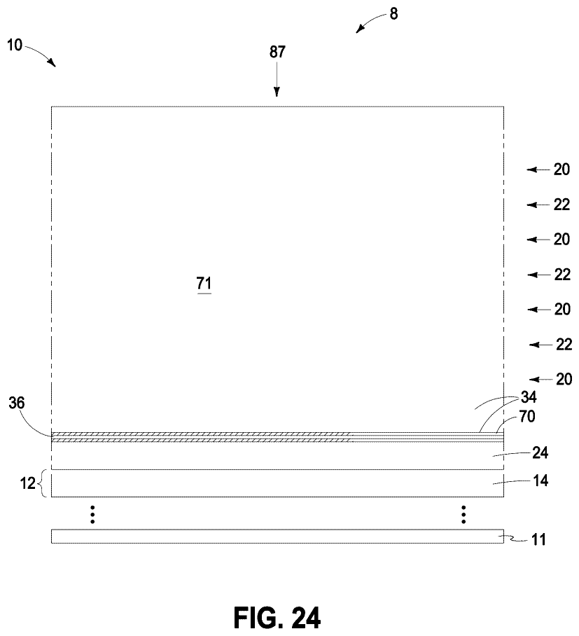

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-27.

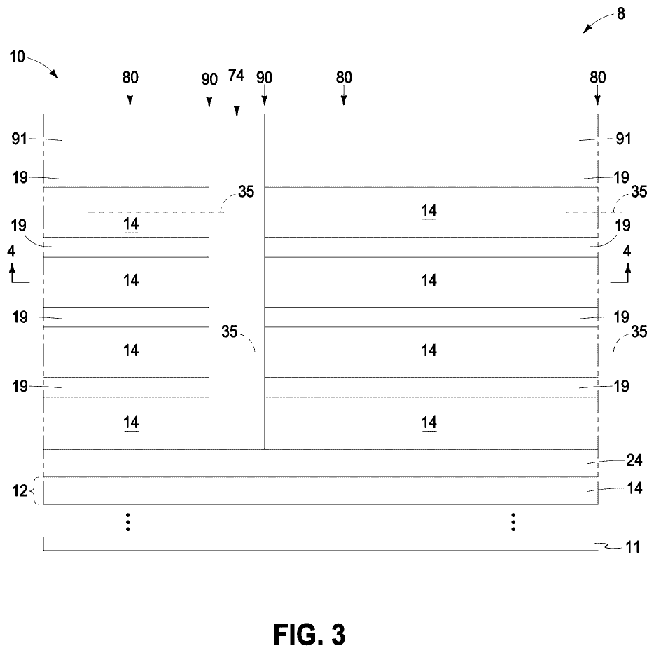

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

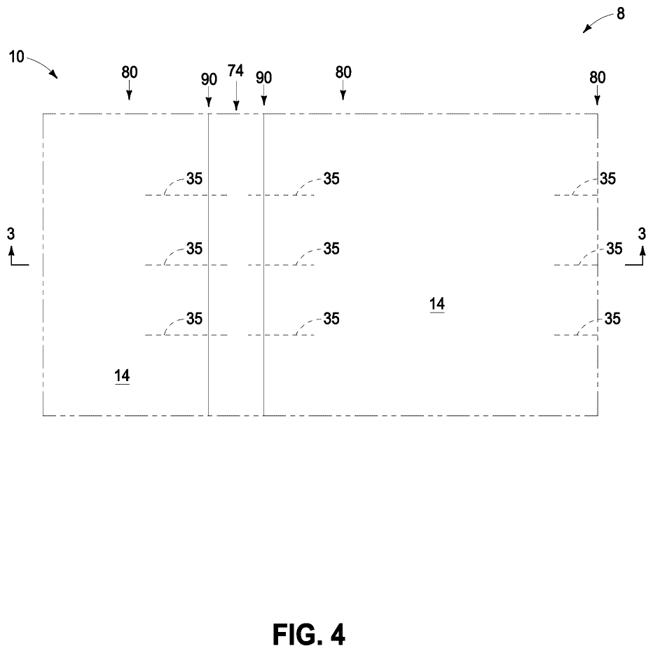

Referring to FIGS. 3 and 4, an example substrate construction 8 in process comprises an array or array area 10 that has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3 and 4-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide).

Construction 8 has been formed to comprise vertically-alternating layers (e.g., in a vertical stack) comprising silicon material 14 (e.g., elemental monocrystalline, epitaxial, or polycrystalline silicon and which may include one or more additional elements) and silicon-germanium material 19 (e.g., Si₁₋ₓGeₓ and which may include one or more additional elements) directly above substrate 11. An example hardmask 91 (e.g., silicon dioxide) is atop construction 8. In a finished memory-circuitry construction, and in one embodiment, memory cells (not-yet-shown) of the memory circuitry individually comprise a horizontal transistor (not-yet-shown) comprising part of silicon material 14 and having a top gate (not-yet-shown), a bottom gate (not-yet-shown), channel material comprising silicon material 14 between the top and bottom gates, a capacitor side (e.g., 80), and a digitline side (e.g., 90). Such memory cells will comprise a capacitor (not-yet-shown) on the capacitor side and part of a digitline (not-yet-shown) on the digitline side. The horizontal transistor and the digitline part will be horizontally spaced relative one another along an axis 35 (only four being designated in FIG. 3 for clarity). In one embodiment and as shown, a horizontally-elongated trench 74 has been formed through construction 8 on digitline side 90.

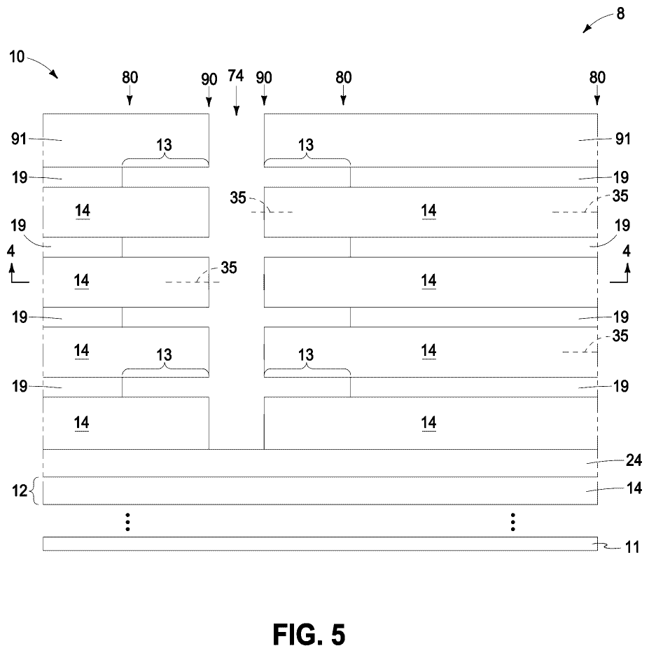

Referring to FIG. 5, a horizontal portion 13 of the layers comprising silicon-germanium material 19 has been removed from digitline side 90 (e.g., through trench 74; e.g., by isotropic etching that may be selective or partially non-selective relative to silicon material 14).

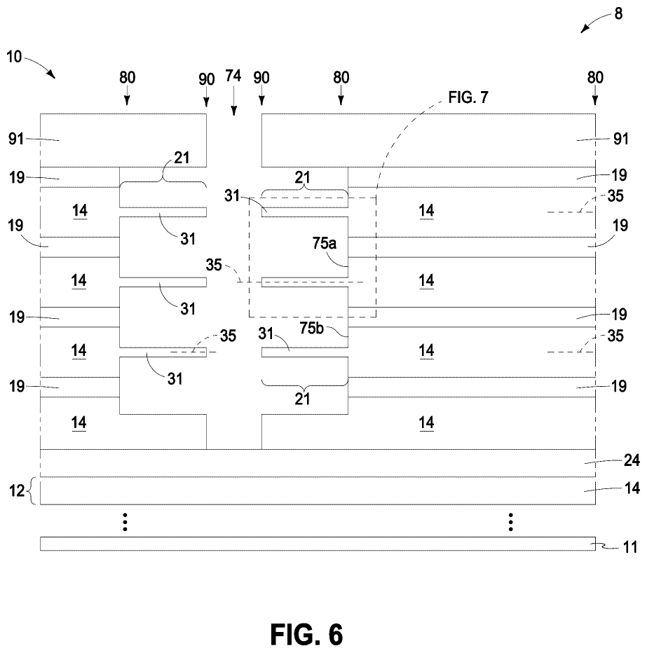

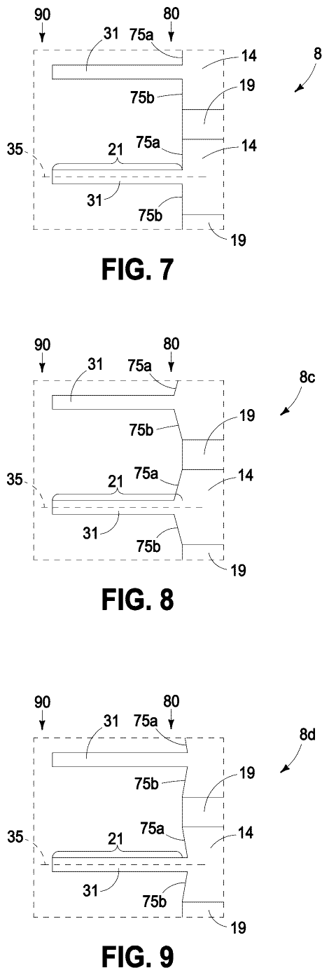

Referring to FIGS. 6 and 7, and after the removing of FIG. 5, a horizontal portion 21 of silicon-material layers 14 from digitline side 90 has been vertically thinned (e.g., by etching) to form a thinned portion 31 of silicon material 14 in individual of silicon-material layers 14. The thinned portion 31 extends from digitline side 90 to capacitor side 80. The vertically thinning forms a linearly-straight surface 75* of silicon material 14 above (e.g., 75a) and below (e.g., 75b) thinned portion 31 on capacitor side 80 in a vertical cross-section that is through and horizontally-elongated along axis 35 (e.g., FIG. 6 or 7 being such a cross-section) (an * being used as a suffix to be inclusive of all such same-numerically-designated structures or portions thereof that may or may not have other suffixes). The artisan is capable of selecting various etching chemistries to achieve the various results stated in this document. For example, and by way of example only, the artisan understands that silicon can be etched wet or dry using a suitable fluorine-containing precursor. In one embodiment, silicon material 14 is vertically thinned by dry etching using an etching chemistry that comprises a fluorine-containing precursor (e.g., a fluorocarbon such as CF₄, C₂F₆, C₃F₈, etc., a hydrofluorocarbon such as H₃CF, H₂CF₂, H₂C₂F₄, etc., and F₂) and that may or may not include one or more other non-fluorine containing precursor(s). Linearly-straight surface 75* is one of vertical, angled from vertical away from capacitor side 80 by no more than 40°, or angled from vertical toward capacitor side 80 by no more than 30°.

In one embodiment, linearly-straight surface is vertical as shown in FIGS. 6 and 7. FIGS. 8 and 9 show example alternate-embodiment constructions 8c and 8d, respectively. Like numerals from the above-described embodiments have been used where appropriate, with some construction differences being indicated with the suffix “c” or “d”, respectively. In one embodiment, linearly-straight surface 75* is angled from vertical away from capacitor side 80 (FIG. 8) by no more than 40°, in one embodiment by no more than 25°, in one embodiment by no more than 10°, and in one embodiment by no more than 5°(15° being shown). In one embodiment, linearly-straight surface 75* is angled from vertical toward capacitor side 80 (FIG. 9) by no more than 30°, in one embodiment by no more than 20°, in one embodiment by no more than 10°, and in one embodiment by no more than 5°(10° being shown). Any other attribute(s) or aspect(s) as shown and/or described herein with respect to other embodiments may be used.

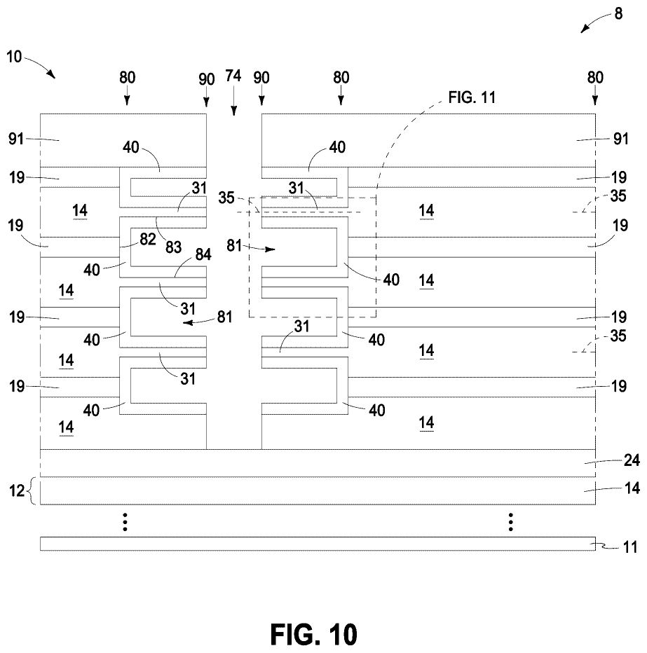

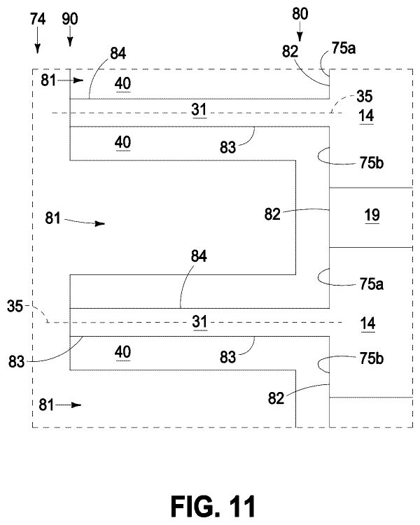

Referring to FIGS. 10 and 11, immediately-vertically-adjacent thinned portions 31 (there being no other such between those that are immediately-vertically-adjacent one another) may be considered as having a space 81 therebetween, such space 81 having a side 82, a top 83, and a bottom 84. In one embodiment and as shown, side 82, top 83, and bottom 84 of space 81 have been lined with insulator material 40 (e.g., silicon nitride) that is aside (e.g., directly against) linearly-straight surface 75b that extends downwardly from an upper of immediately-vertically-adjacent thinned portions 31 and that is aside (e.g., directly against) linearly-straight surface 75a extending upwardly from a lower of immediately-vertically-adjacent thinned portions 31. Insulator material 40 may be deposited conformally within trench 74 and spaces 81 followed by removing (e.g., by anisotropic etch) of insulator material 40 from trench 74 as shown. In some embodiments, surface 75a is referred to as upper linearly-straight surface 75a and surface 75b is referred to as lower linearly-straight surface 75b.

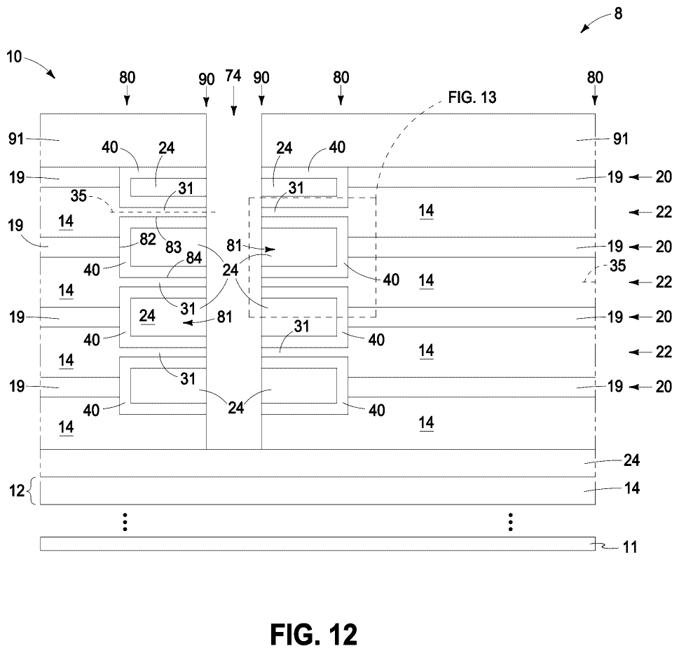

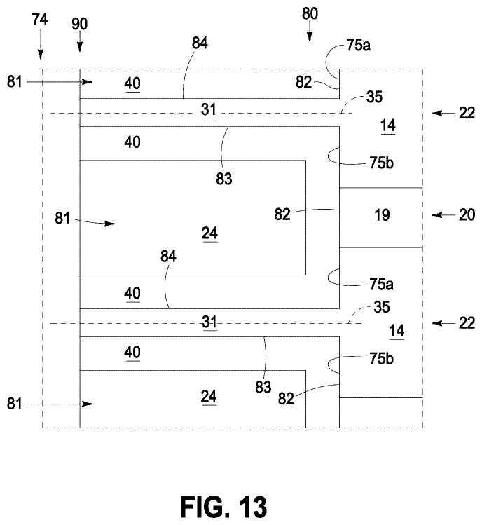

Referring to FIGS. 12 and 13, the finished construction of the memory circuitry will comprise vertically-alternating memory-cell tiers 22* comprising silicon material 14 and insulative tiers 20. In one embodiment and as shown, insulative material 24 of insulative tiers 20 has been formed in remaining of space 81 after the lining of side 82, top 83, and bottom 84 thereof. In such embodiment, insulative material 24 and insulator material 40 are of different compositions relative one another. Insulative material 24 may be deposited conformally within trench 74 and remaining of spaces 81 followed by removing (e.g., by anisotropic etch) of insulative material 24 from trench 74 as shown.

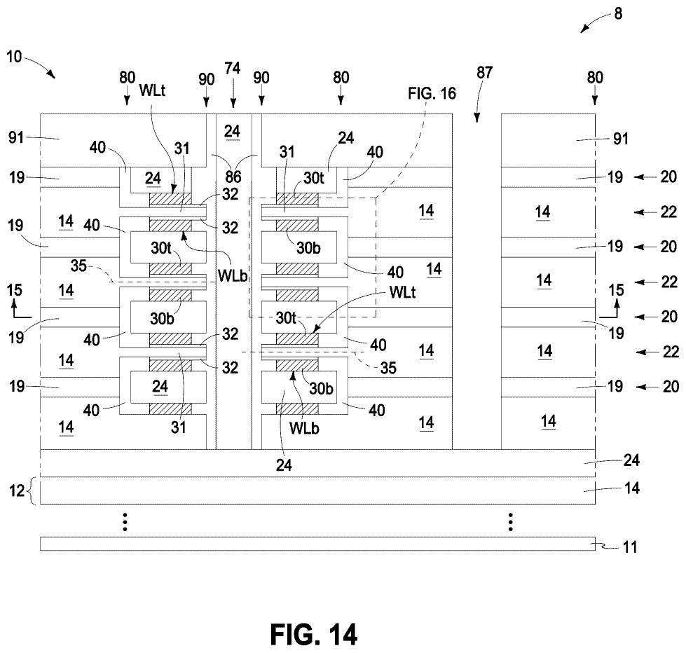

Referring to FIGS. 14-16, a gate insulator 32 (e.g., silicon dioxide, hafnium oxide, silicon nitride, etc.) and a gate 30* of the horizontal transistor have been formed, with gate 30* comprising a top gate 30t and a bottom gate 30b (e.g., after forming thinned portion 31). In one embodiment, top gate 30t is part of one of a plurality of top horizontal conductive access lines WLt and bottom gate 30b is part of one of a plurality of bottom horizontal conductive access lines WLb, with the one top horizontal conductive access line and the one bottom horizontal conductive access line together directly electrically coupling together multiple of the top and bottom gates of different ones of the horizontal transistors being formed that are in the same memory-cell tier 22*. By way of example only, top gate 30t and bottom gate 30b may be formed by etching back insulator material 40 of FIGS. 12 and 13 selectively relative to silicon material 14, gate insulator 32, and insulative material 24. This may be followed by deposition of conductive material of the top and bottom gates to within void-space left from such etching back of insulator material 40, followed by etching back such conductive material to produce the outlines of top and bottom gates 30t and 30b as shown. Then, insulating material 86 (e.g., silicon nitride) may be deposited to fill remaining volume of the void-space on digitline side 90 of top and bottom gates 30t and 30b and to line and less-than-fill trench 74. This may be followed by deposition of more insulative material 24 to fill remaining volume of trench 74 as shown. Thereafter, a horizontally-elongated trench 87 has been formed through construction 8 on capacitor side 80. Gate insulator 32 may be formed before forming insulator material 40 (not shown), formed by oxidizing (when such comprises an insulative oxide) exposed surfaces of thinned portions 31 regardless of when so-doing, and/or depositing such into the above-described void-space immediately before forming conductive material of gate 30* therein.

In one embodiment and as shown, length L1 of upper linearly-straight surface 75a and length L2 of lower linearly-straight surface 75b (L1 and L2 may be equal or not) are individually greater than vertical thickness T1 and T2 (which may be equal or not) of each of top gate 30t and bottom gate 30b, respectively. Regardless, in one embodiment and as shown, upper linearly-straight surface 75a extends to higher than an uppermost surface 88 of top gate 30t that is aside upper linearly-straight surface 75a and lower linearly-straight surface 75b extends to lower than a lowest surface 89 of bottom gate 30b that is aside lower linearly-straight surface 75b.

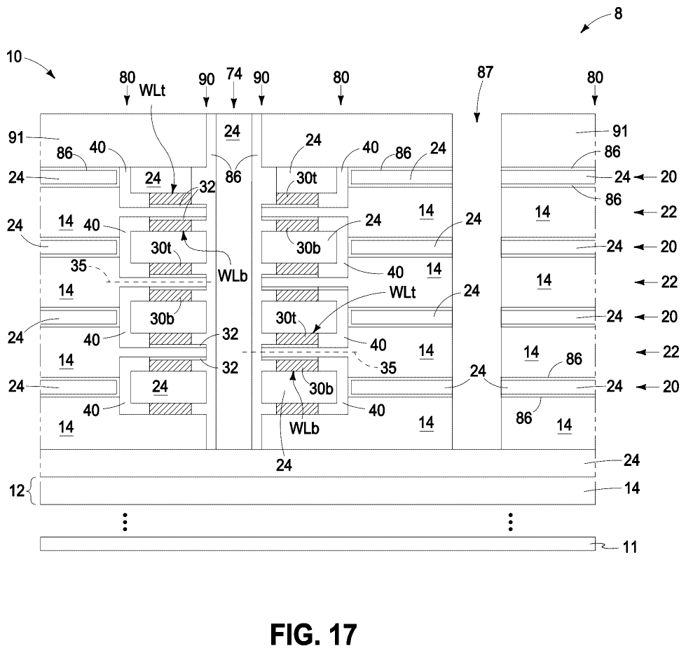

Referring to FIG. 17, through trench 87, remaining silicon-germanium material 19 (no longer shown) has been removed (e.g., by etching selectively relative to silicon material 14) and replaced by insulating material 86 and insulative material 24.

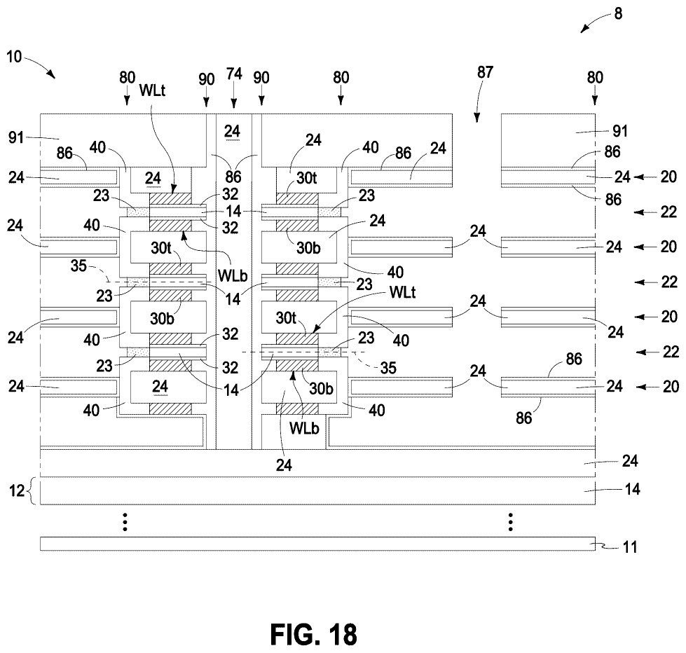

Referring to FIG. 18, through trench 87, silicon material 14 has been removed back as shown (e.g., by etching with tetramethyl ammonium hydroxide) to leave a suitable portion of silicon material 14 extending beyond capacitor side 80 of top and bottom gates 30t and 30b as shown. This has been followed by conductively doping silicon material 14 through trench 87 (e.g., by gas diffusion doping) to form capacitor-side first source/drain regions 23 of the horizontal transistor being formed.

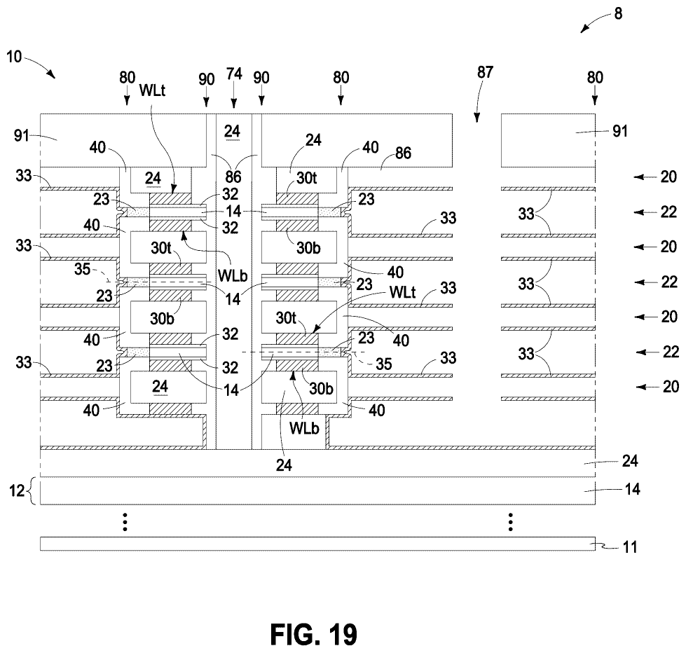

Referring to FIG. 19, conductive material (e.g., conductive metal material) of a first capacitor electrode 33 (e.g., a storage-node electrode) has been conformally deposited with trench 87 and surfaces there-within. Such conductive material has subsequently been removed (e.g., by anisotropic etching) to expose ends of by insulative material 24 and insulating material 86 that is exposed to trench 87 (no longer being shown). This has been followed by selectively etching such insulative material 24 and insulating material 86 (neither longer being shown) to leave first capacitor electrodes 33 as shown.

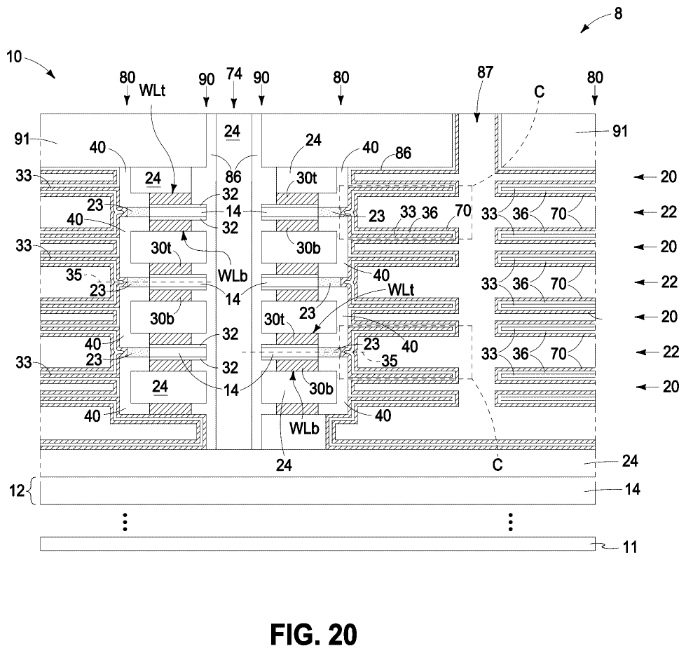

Referring to FIG. 20, a capacitor insulator 36 (e.g., dielectric or ferroelectric) and a second capacitor electrode 34 (e.g., comprising conductive metal material 70 and conductively-doped polysilicon 71) have been formed in trench 87, thereby forming capacitors C. Example second capacitor electrodes 34 of multiple capacitors C are directly electrically coupled with one another. Example first capacitor electrode 33 is directly coupled to first source/drain region 23.

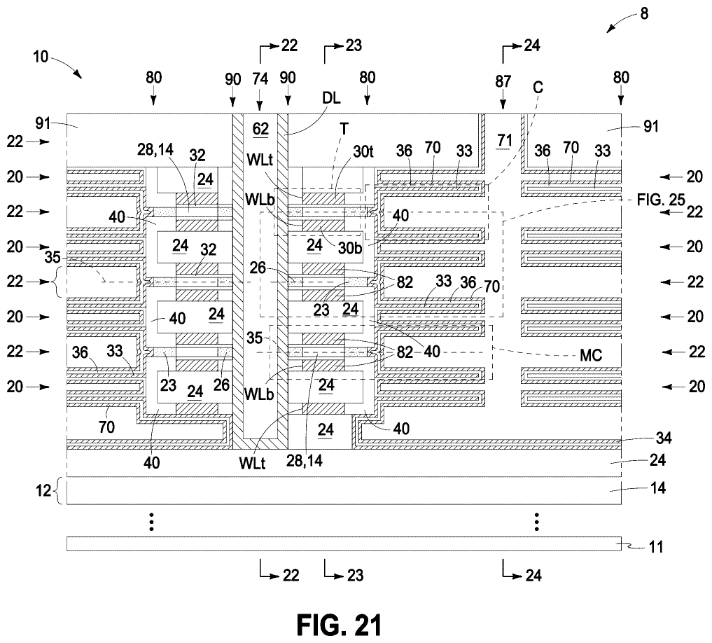

Referring to FIGS. 21-25, insulative material 24 has been removed from trench 74 (no longer there shown) and insulating material 86 has been etched back to expose silicon material 14 on digitline side 90. This has been followed by conductively doping silicon material 14 through trench 74 (e.g., by gas diffusion doping) to form digitline-side second source/drain regions 26, with a channel region 28, 14 being horizontally between first and second source/drain regions 23 and 26, thus forming a horizontal transistor T. Regions 23, 26, and 28, 14 of different immediately-horizontally-adjacent memory cells MC into and out of the plane of the page upon which FIG. 21 lies in a common memory-cell tier 22* may be isolated relative one another by insulative material (not shown). After forming second source/drain regions 26, digitlines DL have been formed in trench 74 to directly electrically couple with individual second source/drain regions 26, thus forming memory cells MC comprising one of horizontal transistors T and one of capacitors C. Example insulator material 62 (e.g., silicon dioxide and/or silicon nitride) has subsequently been formed in trench 74 and between immediately-adjacent digitlines DL. Capacitors C and digitlines DL may be formed in any order relative one another.

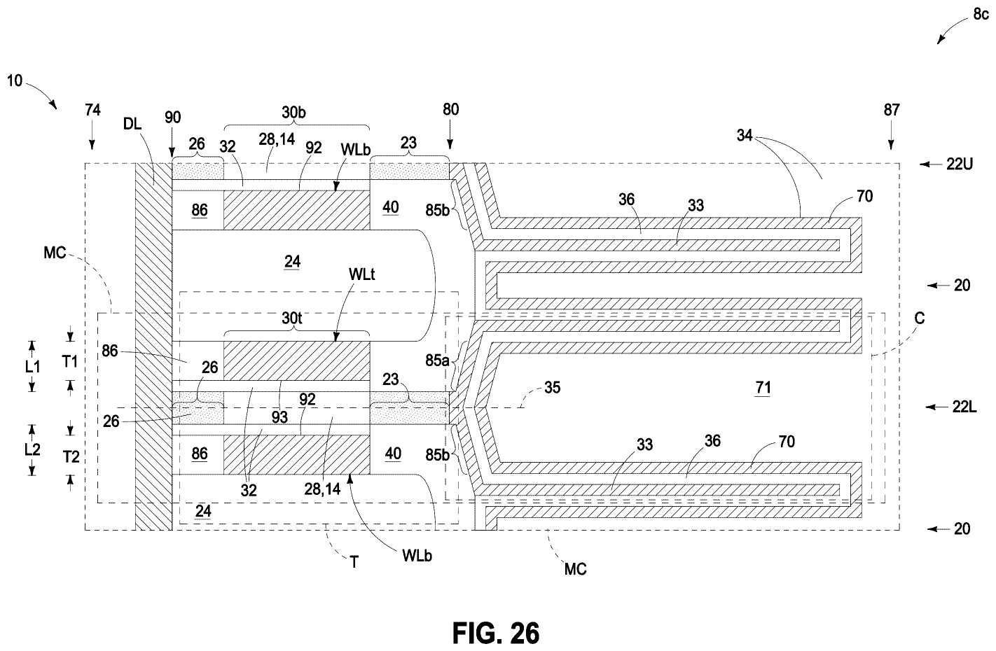

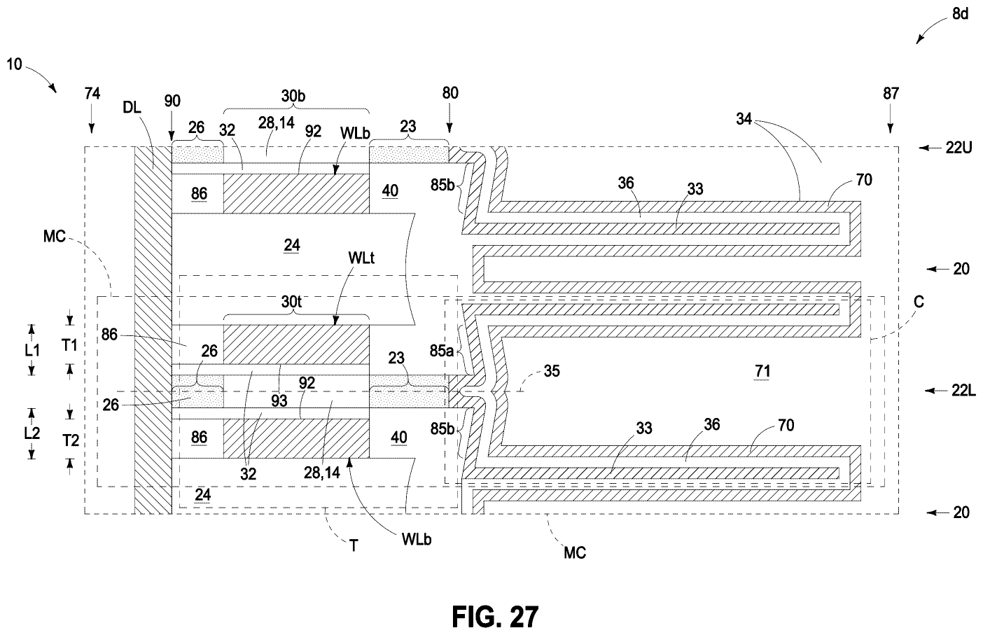

FIGS. 26 and 27 show example resultant constructions 8c and 8d, respectively, as may result from subsequent processing from constructions 8c and 8d in FIGS. 8 and 9, or otherwise, and independent of method in structure embodiments. Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

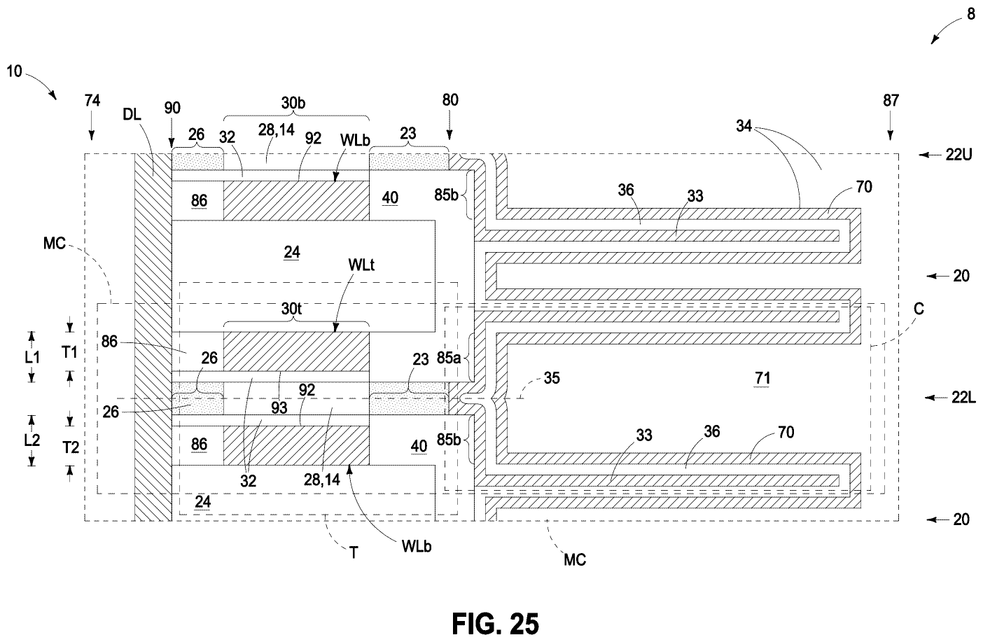

In one embodiment, memory circuitry (e.g., 8, 8c, 8d) comprises vertically-alternating insulative tiers (e.g., 20) and memory-cell tiers (e.g., 22*). Memory cells (e.g., MC) are in the memory-cell tiers and individually comprise a horizontal transistor (e.g., T), a capacitor (e.g., C) that is on a capacitor side (e.g., 80) of the horizontal transistor, and part of a digitline (e.g., DL) that is on a digitline side (e.g., 90) of the horizontal transistor. The capacitor, the horizontal transistor, and the digitline part are horizontally spaced relative one another along an axis (e.g., 35). The horizontal transistor has a gate (e.g., 30*) that comprises a top gate (e.g., 30t; e.g., that is part of one of a plurality of top horizontal conductive access lines [e.g., WLt]) and a bottom gate (e.g., 30b; e.g., that is part of one of a plurality of bottom horizontal conductive access lines [e.g., WLb]) having channel material (e.g., 28, 14) therebetween. Immediately-vertically-adjacent of the memory-cell tiers comprise an upper memory-cell tier (e.g., 22U in FIGS. 25-27) and a lower memory-cell tier (e.g., 22L in FIGS. 25-27). Insulator material (e.g., 40) extends from horizontally aside the capacitor side of the top gate in the lower memory-cell tier through the insulative tier that is between the upper and lower memory-cell tiers to horizontally aside the capacitor side of the bottom gate in the upper memory-cell tier. The insulator material in the upper memory-cell tier and in the lower memory-cell tier has a laterally-outer linearly-straight surface (e.g., 85* in FIGS. 25-27) in a vertical cross-section (e.g., that of FIGS. 21, 25, 26, or 27) that is through and horizontally-elongated along the axis. The laterally-outer linearly-straight surface is one of vertical (e.g., construction 8), angled from vertical toward the capacitor side by no more than 40° (e.g., construction 8c), or angled from vertical away from the capacitor side by no more than 30° (e.g., construction 8d).

In one embodiment, the insulative tier that is between the upper and lower memory-cell tiers at least predominantly comprises an insulative material (e.g., 24; e.g., silicon dioxide) where the insulator material passes therethrough, with the insulator material (e.g., silicon nitride) and the insulative material being of different compositions relative one another.

In one embodiment, length of the laterally-outer linearly-straight surface in the upper memory-cell tier (e.g., L1) and length of the linearly-straight surface in the lower memory-cell tier (e.g., L2) are individually greater than vertical thickness of each of the top gate and the bottom gate (e.g., T1 and T2, respectively). In one embodiment, the laterally-outer linearly-straight surface (e.g., 85b) in the upper memory-cell tier extends to higher than an uppermost surface (e.g., 92) of the bottom gate in the upper memory-cell tier and the laterally-outer linearly-straight surface (e.g., 85a) in the lower memory-cell tier extends to lower than a lowest surface (e.g., 93) of the top gate in the lower memory-cell tier.

In prior methods, the example etching shown by FIGS. 6 and 7 would form silicon-material surfaces 75a and 75b to be curved away from capacitor side 80. This would result in corresponding silicon nitride surfaces 85a and 85b also being so curved. This tended to make a determined or desired etch-stop point for the etch of silicon material 14 in the processing of FIG. 18 variable, for example depending on depth of a given memory-cell tier 22* in the construction. This would lead to different lengths for different capacitor-side source/drain region 23 in different depths in the construction, which is highly undesirable. Formation of silicon-material surfaces 75a and 75b as described herein may reduce or eliminate such issues.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time. The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming vertically-alternating layers comprising silicon material and silicon-germanium material directly above a substrate. The silicon-material layers comprise part of horizontal transistors in a finished construction of the memory circuitry. Individual memory cells of the memory circuitry comprise one of the horizontal transistors, a capacitor that is on a capacitor side of the horizontal transistor, and part of a digitline that is on a digitline side of the horizontal transistor. The capacitor, the horizontal transistor and the digitline part are horizontally spaced relative one another along an axis. The horizontal transistor has a gate that comprises a top gate and a bottom gate having channel material comprising the silicon material therebetween. A horizontal portion of the layers comprising the silicon-germanium material is removed from the digitline side. After the removing, a horizontal portion of the silicon-material layers is vertically thinned from the digitline side to form a thinned portion of the silicon material in individual of the silicon-material layers. The thinned portion extends from the digitline side to the capacitor side. The vertically thinning forms a linearly-straight surface of the silicon material above and below the thinned portion on the capacitor side in a vertical cross-section that is through and horizontally-elongated along the axis. The linearly-straight surface is one of vertical, angled from vertical away from the capacitor side by no more than 40°, or angled from vertical toward the capacitor side by no more than 30°.

In some embodiments, memory circuitry comprises vertically-alternating insulative tiers and memory-cell tiers. Memory cells in the memory-cell tiers individually comprise a horizontal transistor, a capacitor that is on a capacitor side of the horizontal transistor, and part of a digitline that is on a digitline side of the horizontal transistor. The capacitor, the horizontal transistor, and the digitline part are horizontally spaced relative one another along an axis. The horizontal transistor has a gate that comprises a top gate and a bottom gate having channel material therebetween. Immediately-vertically-adjacent of the memory-cell tiers comprise an upper memory-cell tier and a lower memory-cell tier. Insulator material extends from horizontally aside the capacitor side of the top gate in the lower memory-cell tier through the insulative tier that is between the upper and lower memory-cell tiers to horizontally aside the capacitor side of the bottom gate in the upper memory-cell tier. The insulator material in the upper memory-cell tier and in the lower memory-cell tier has a laterally-outer linearly-straight surface in a vertical cross-section that is through and horizontally-elongated along the axis. The laterally-outer linearly-straight surface is one of vertical, angled from vertical toward the capacitor side by no more than 40°, or angled from vertical away from the capacitor side by no more than 30°.

In some embodiments, memory circuitry comprises vertically-alternating insulative tiers comprising silicon dioxide and memory-cell tiers. Memory cells in the memory-cell tiers individually comprise a horizontal transistor, a capacitor that is on a capacitor side of the horizontal transistor, and part of a digitline that is on a digitline side of the horizontal transistor. The capacitor, the horizontal transistor, and the digitline part are horizontally spaced relative one another along an axis. Immediately-vertically-adjacent of the memory-cell tiers comprise an upper memory-cell tier and a lower memory-cell tier. The horizontal transistor has a gate that comprises a top gate that is part of one of a plurality of top horizontal conductive access lines and comprises a bottom gate that is part of one of a plurality of bottom horizontal conductive access lines. The one top horizontal conductive access line and the one bottom horizontal conductive access line together directly electrically couple together multiple of the top and bottom gates of different ones of the horizontal transistors that are in the same memory-cell tier. Silicon nitride extends from horizontally aside the capacitor side of the top gate in the lower memory-cell tier through the silicon dioxide of the insulative tier that is between the upper and lower memory-cell tiers to horizontally aside the capacitor side of the bottom gate in the upper memory-cell tier. The silicon nitride in the upper memory-cell tier and in the lower memory-cell tier has a laterally-outer linearly-straight surface in a vertical cross-section that is through and horizontally-elongated along the axis. The laterally-outer linearly-straight surface is one of vertical, angled from vertical away from the capacitor side by no more than 40°, or angled from vertical toward the capacitor side by no more than 30°.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating layers comprising silicon material and silicon-germanium material directly above a substrate, the silicon-material layers comprising part of horizontal transistors in a finished construction of the memory circuitry, individual memory cells of the memory circuitry comprising one of the horizontal transistors, a capacitor that is on a capacitor side of the horizontal transistor, and part of a digitline that is on a digitline side of the horizontal transistor; the capacitor, the horizontal transistor and the digitline part being horizontally spaced relative one another along an axis; the horizontal transistor having a gate that comprises a top gate and a bottom gate having channel material comprising the silicon material therebetween;
removing a horizontal portion of the layers comprising the silicon-germanium material from the digitline side; and
after the removing, vertically thinning a horizontal portion of the silicon-material layers from the digitline side to form a thinned portion of the silicon material in individual of the silicon-material layers, the thinned portion extending from the digitline side to the capacitor side, the vertically thinning forming a linearly-straight surface of the silicon material above and below the thinned portion on the capacitor side in a vertical cross-section that is through and horizontally-elongated along the axis; the linearly-straight surface being one of vertical, angled from vertical away from the capacitor side by no more than 40°, or angled from vertical toward the capacitor side by no more than 30°.

2. The method of claim 1 wherein the linearly-straight surface is vertical.

3. The method of claim 1 wherein the linearly-straight surface is angled from vertical away from the capacitor side by no more than 40°.

4. The method of claim 1 wherein the linearly-straight surface is angled from vertical away toward the capacitor side by no more than 30°.

5. The method of claim 1 wherein the vertically thinning comprises dry etching using an etching chemistry that comprises a fluorine-containing precursor.

6. The method of claim 1 comprising lining a side, a top, and a bottom of space that is between immediately-vertically-adjacent of the thinned portions with insulator material that is aside the linearly-straight surface extending downwardly from an upper of the immediately-vertically-adjacent of the thinned portions and that is aside the linearly-straight surface extending upwardly from a lower of the immediately-vertically-adjacent of the thinned portions.

7. The method of claim 6 comprising forming the insulator material directly against each of said linearly-straight surfaces.

8. The method of claim 6 wherein the finished construction of the memory circuitry comprises vertically-alternating memory-cell tiers comprising the silicon material and insulative tiers, and further comprising forming insulative material of the insulative tiers in remaining of the space after the lining of the side, the top, and the bottom of the space; the insulative material and the insulator material being of different compositions relative one another.

9. The method of claim 1 wherein,
the linearly-straight surface of the silicon material that is above the thinned portion is an upper linearly-straight surface and the linearly-straight surface of the silicon material that is below the thinned portion is a lower linearly-straight surface;
the top gate and the bottom gate are formed after forming the thinned portion; and
length of the upper linearly-straight surface and length of the lower linearly-straight surface are individually greater than vertical thickness of each of the top gate and the bottom gate.

10. The method of claim 1 wherein,
the linearly-straight surface of the silicon material that is above the thinned portion is an upper linearly-straight surface and the linearly-straight surface of the silicon material that is below the thinned portion is a lower linearly-straight surface;
the top gate and the bottom gate are formed after forming the thinned portion; and
the upper linearly-straight surface extends to higher than an uppermost surface of the top gate that is aside the upper linearly-straight surface; and
the lower linearly-straight surface extends to lower than a lowest surface of the bottom gate that is aside the lower linearly-straight surface.

11. : The method of claim 10 wherein length of the upper linearly-straight surface and length of the lower linearly-straight surface are individually greater than vertical thickness of each of the top gate and the bottom gate.

12. Memory circuitry comprising:
vertically-alternating insulative tiers and memory-cell tiers; memory cells in the memory-cell tiers that individually comprise a horizontal transistor, a capacitor that is on a capacitor side of the horizontal transistor, and part of a digitline that is on a digitline side of the horizontal transistor; the capacitor, the horizontal transistor, and the digitline part being horizontally spaced relative one another along an axis; the horizontal transistor having a gate that comprises a top gate and a bottom gate having channel material therebetween, immediately-vertically-adjacent of the memory-cell tiers comprising an upper memory-cell tier and a lower memory-cell tier; and
insulator material that extends from horizontally aside the capacitor side of the top gate in the lower memory-cell tier through the insulative tier that is between the upper and lower memory-cell tiers to horizontally aside the capacitor side of the bottom gate in the upper memory-cell tier, the insulator material in the upper memory-cell tier and in the lower memory-cell tier having a laterally-outer linearly-straight surface in a vertical cross-section that is through and horizontally-elongated along the axis; the laterally-outer linearly-straight surface being one of vertical, angled from vertical toward the capacitor side by no more than 40°, or angled from vertical away from the capacitor side by no more than 30°.

13. The memory circuitry of claim 12 wherein the laterally-outer linearly-straight surface is vertical.

14. The memory circuitry of claim 12 wherein the laterally-outer linearly-straight surface is angled from vertical toward the capacitor side by no more than 40°.

15. The memory circuitry of claim 14 wherein the laterally-outer linearly-straight surface is angled from vertical toward the capacitor side by no more than 25°.

16. The memory circuitry of claim 14 wherein the laterally-outer linearly-straight surface is angled from vertical toward the capacitor side by no more than 10°.

17. The memory circuitry of claim 14 wherein the laterally-outer linearly-straight surface is angled from vertical away from the capacitor side by no more than 5°.

18. The memory circuitry of claim 12 wherein the laterally-outer linearly-straight surface is angled from vertical toward the capacitor side by no more than 30°.

19. The memory circuitry of claim 18 wherein the laterally-outer linearly-straight surface is angled from vertical toward the capacitor side by no more than 20°.

20. The memory circuitry of claim 18 wherein the laterally-outer linearly-straight surface is angled from vertical toward the capacitor side by no more than 10°.

21. The memory circuitry of claim 18 wherein the laterally-outer linearly-straight surface is angled from vertical toward the capacitor side by no more than 5°.

22. The memory circuitry of claim 12 wherein the insulative tier that is between the upper and lower memory-cell tiers at least predominantly comprises an insulative material where the insulator material passes therethrough, the insulator material and the insulative material being of different compositions relative one another.

23. The memory circuitry of claim 12 wherein length of the laterally-outer linearly-straight surface in the upper memory-cell tier and length of the laterally-outer linearly-straight surface in the lower memory-cell tier are individually greater than vertical thickness of each of the top gate and the bottom gate.

24. The memory circuitry of claim 12 wherein,
the laterally-outer linearly-straight surface in the upper memory-cell tier extends to higher than an uppermost surface of the bottom gate in the upper memory-cell tier; and
the laterally-outer linearly-straight surface in the lower memory-cell tier extends to lower than a lowest surface of the top gate in the lower memory-cell tier.

25. The memory circuitry of claim 24 wherein length of the laterally-outer linearly-straight surface in the upper memory-cell tier and length of the laterally-outer linearly-straight surface in the lower memory-cell tier are individually greater than vertical thickness of each of the top gate and the bottom gate.

26. Memory circuitry comprising:
vertically-alternating insulative tiers comprising silicon dioxide and memory-cell tiers; memory cells in the memory-cell tiers that individually comprise a horizontal transistor, a capacitor that is on a capacitor side of the horizontal transistor, and part of a digitline that is on a digitline side of the horizontal transistor; the capacitor, the horizontal transistor, and the digitline part being horizontally spaced relative one another along an axis, immediately-vertically-adjacent of the memory-cell tiers comprising an upper memory-cell tier and a lower memory-cell tier;
the horizontal transistor having a gate that comprises a top gate that is part of one of a plurality of top horizontal conductive access lines and comprises a bottom gate that is part of one of a plurality of bottom horizontal conductive access lines, the one top horizontal conductive access line and the one bottom horizontal conductive access line together directly electrically coupling together multiple of the top and bottom gates of different ones of the horizontal transistors that are in the same memory-cell tier; and
silicon nitride that extends from horizontally aside the capacitor side of the top gate in the lower memory-cell tier through the silicon dioxide of the insulative tier that is between the upper and lower memory-cell tiers to horizontally aside the capacitor side of the bottom gate in the upper memory-cell tier, the silicon nitride in the upper memory-cell tier and in the lower memory-cell tier having a laterally-outer linearly-straight surface in a vertical cross-section that is through and horizontally-elongated along the axis; the laterally-outer linearly-straight surface being one of vertical, angled from vertical away from the capacitor side by no more than 40°, or angled from vertical toward the capacitor side by no more than 30°.

27. The memory circuitry of claim 26 wherein the laterally-outer linearly-straight surface is vertical.

28. The memory circuitry of claim 26 wherein the laterally-outer linearly-straight surface is angled from vertical away from the capacitor side by no more than 40°.

29. The memory circuitry of claim 26 wherein the laterally-outer linearly-straight surface is angled from vertical toward the capacitor side by no more than 30°.
